(19) United States
(12) Patent Application Publication
(10) Pub. No.: US 2013/0001558 A1
(43) Pub. Date: Jan. 3, 2013

(54) SEMICONDUCTOR DEVICE AND MANUFACTURING METHOD OF SEMICONDUCTOR DEVICE

(75) Inventors: Naoya Okada, Tsukuba (JP); Takeshi Noda, Mobara (JP)

(73) Assignee: Hitachi Displays, Ltd.

(21) Appl. No.: 13/533,304

(22) Filed: Jun. 26, 2012

(30) Foreign Application Priority Data
Jun. 29, 2011 (JP) 2011-144698

(51) Int. Cl. H01L 29/78; H01L 21/36; H01L 29/04

(52) U.S. Cl. 257/57; 438/478; 257/E29.003; 257/E29.255; 257/E21.461

(57) ABSTRACT

A semiconductor device includes a gate electrode, a gate insulating film provided so as to cover one surface of the gate electrode, an oxide semiconductor provided so as to overlap the gate insulating film, and a source electrode and a drain electrode, which are provided so as to overlap the oxide semiconductor. The semiconductor device also includes an oxygen-atom-containing film provided between the gate insulating film, and, the source electrode and the drain electrode, so as to be held in contact with the oxide semiconductor.

### CROSS-REFERENCE TO RELATED APPLICATION

The present application claims priority from Japanese application JP 2011-144698 filed on Jun. 29, 2011, the content of which is hereby incorporated by reference into this application.

### BACKGROUND OF THE INVENTION

1. Field of the Invention

The present invention relates to a semiconductor device and a manufacturing method for a semiconductor device.

2. Description of the Related Art

In recent years, a thin film transistor (TFT) using an oxide semiconductor layer is known (see Japanese Patent Application Laid-open No. 2010-171406). Specifically, a thin film transistor disclosed in Japanese Patent Application Laid-open No. 2010-171406 includes a gate electrode layer, a gate insulating layer provided on the gate electrode, an oxide semiconductor layer provided on the gate insulating layer, and a source/drain electrode layer provided on the oxide semiconductor layer. In order to improve mobility of the thin film transistor and to suppress an increase in an OFF-current, the thin film transistor includes a plurality of oxide clusters having conductivity on the gate insulating layer.

### SUMMARY OF THE INVENTION

In general, for the thin film transistor using the oxide semiconductor as described above, vapor annealing is performed after the formation of the thin film transistor. As a result, oxygen atoms (for example, O or OH) diffuse into the oxide semiconductor to improve characteristics such as the mobility of the thin film transistor.

In the thin film transistor, however, it is difficult to sufficiently and uniformly diffuse the oxygen atoms and the like into the oxide semiconductor. Moreover, it is necessary to perform the vapor annealing at high temperature over a long time so as to more sufficiently diffuse the oxygen atoms into the oxide semiconductor.

In view of the problem described above, one or more embodiments of the present invention has an object to realize a semiconductor device including a thin film transistor using an oxide semiconductor at a semiconductor layer, which improves characteristics of the thin film transistor by sufficiently and uniformly diffusing oxide atoms and the like into the oxide semiconductor, and to realize a manufacturing method for the semiconductor device.

(1) A semiconductor device according to the present invention includes a gate electrode, a gate insulating film provided so as to cover one surface of the gate electrode, an oxide semiconductor provided so as to overlap the gate insulating film, and a source electrode and a drain electrode, which are provided so as to overlap the oxide semiconductor. The semiconductor device also includes an oxygen-atom-containing film provided between the gate insulating film, and, the source electrode and the drain electrode, so as to be held in contact with the oxide semiconductor.

(2) In the semiconductor device according to the above-mentioned item (1), the oxide semiconductor includes a first oxide semiconductor layer and a second oxide semiconductor layer, and the oxygen-atom-containing film is provided between the first oxide semiconductor layer and the second oxide semiconductor layer.

(3) In the semiconductor device according to the above-mentioned item (1) or (2), the oxygen-atom-containing film is a water-containing film containing water.

(4) In the semiconductor device according to the above-mentioned item (3), a water concentration of the water-containing film is higher than a water concentration of the oxide semiconductor.

(5) In the semiconductor device according to the above-mentioned item (3) or (4), a water concentration of the water-containing film is 1 atm % to 30 atm %.

(6) In the semiconductor device according to at least one of the above-mentioned items (1) to (5), the oxygen-atom-containing film is provided at a position corresponding to 20% to 80% of a thickness of the oxide semiconductor.

(7) In the semiconductor device according to at least one of the above-mentioned items (1) to (6), the oxygen-atom-containing film is formed as a discontinuous film.

(8) In the semiconductor device according to at least one of the above-mentioned items (1) to (7), a thickness of the oxide semiconductor is 5 nm to 200 nm,

(9) In the semiconductor device according to at least one of the above-mentioned items (1) to (8), a material of the first oxide semiconductor layer is different from a material of the second oxide semiconductor layer.

(10) A manufacturing method for a semiconductor device according to the present invention includes: forming at least a first electrode layer on a substrate, forming a channel layer including an oxide semiconductor layer and an oxygen-atom-containing film on the substrate on which the at least the first electrode layer is formed; forming at least a second electrode layer on the substrate on which the channel layer is formed, and diffusing oxygen atoms contained in the oxygen-atom-containing film into the oxide semiconductor layer.

(11) In the manufacturing method for a semiconductor device according to the above-mentioned item (10), the oxide semiconductor layer includes a first oxide semiconductor layer and a second oxide semiconductor layer. The forming a channel layer includes forming at least the first oxide semiconductor layer on the substrate on which the at least the first electrode layer is formed, forming the oxygen-atom-containing film on the first oxide semiconductor layer, and forming the second oxide semiconductor layer on the oxygen-atom-containing film.

### BRIEF DESCRIPTION OF THE DRAWINGS

In the accompanying drawings:

FIG. 1 is a schematic diagram illustrating a display apparatus according to a first embodiment of the present invention;

FIG. 2 is a conceptual view illustrating a pixel circuit formed on a TFT substrate illustrated in FIG. 1;

FIG. 3 is a view for illustrating a configuration of a TFT illustrated in FIG. 2;

FIG. 4 is a view for illustrating a configuration of a cross section of the TFT illustrated in FIG. 2;

FIG. 5A is a view illustrating a sectional structure in one step of a flow of a manufacturing method according to the first embodiment;

FIG. 5B is a view illustrating a sectional structure in another step of the flow of the manufacturing method according to the first embodiment;

FIG. 5C is a view illustrating a sectional structure in a further step of the flow of the manufacturing method according to the first embodiment;

FIG. 5D is a view illustrating a sectional structure in a further step of the flow of the manufacturing method according to the first embodiment;

FIG. 5E is a view illustrating a sectional structure in a further step of the flow of the manufacturing method according to the first embodiment;

FIG. 5F is a view illustrating a sectional structure in a further step of the flow of the manufacturing method according to the first embodiment;

FIG. 5G is a view illustrating a sectional structure in a further step of the flow of the manufacturing method according to the first embodiment;

FIG. 6 is a flowchart for illustrating the flow of the manufacturing method according to the first embodiment;

FIG. 7 is a view for illustrating a configuration of a cross section of a TFT according to a second embodiment of the present invention;

FIG. 8A is a view illustrating a sectional structure in one step of a flow of a manufacturing method according to the second embodiment;

FIG. 8B is a view illustrating a sectional structure in another step of the flow of the manufacturing method according to the second embodiment;

FIG. 8C is a view illustrating a sectional structure in a further step of the flow of the manufacturing method according to the second embodiment;

FIG. 8D is a view illustrating a sectional structure in a further step of the flow of the manufacturing method according to the second embodiment;

FIG. 8E is a view illustrating a sectional structure in a further step of the flow of the manufacturing method according to the second embodiment;

FIG. 8F is a view illustrating a sectional structure in a further step of the flow of the manufacturing method according to the second embodiment;

FIG. 8G is a view illustrating a sectional structure in a further step of the flow of the manufacturing method according to the second embodiment; and

FIG. 9 is a flowchart for illustrating the flow of the manufacturing method according to the second embodiment.

### DETAILED DESCRIPTION OF THE INVENTION

Hereinafter, embodiments of the present invention are described referring to the accompanying drawings. In the drawings, the same or similar components are denoted by the same reference numerals, and the overlapping description thereof is herein omitted.

### First Embodiment

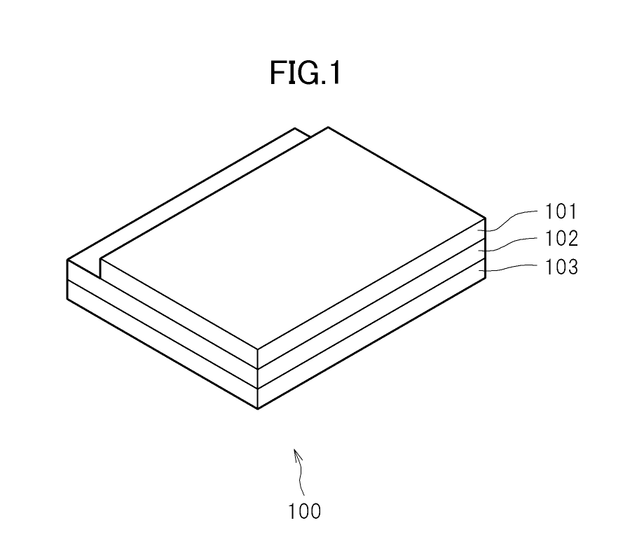

FIG. 1 is a schematic diagram illustrating a display apparatus according to an embodiment of the present invention. As illustrated in FIG. 1, a display apparatus 100 includes, for example, a TFT substrate 102 and a filter substrate 101. On the TFT substrate 102, TFTs and the like (not shown) are formed. The filter substrate 101 is opposed to the TFT substrate 102 and is provided with color filters (not shown). The display apparatus 100 also includes a liquid crystal material (not shown) and a backlight unit 103. The liquid crystal material is sealed in a region sandwiched between the TFT substrate 102 and the filter substrate 101. The backlight unit 103 is provided on the TFT substrate 102 so as to be held in contact with a surface opposite to the side on which the filter substrate 101 is provided.

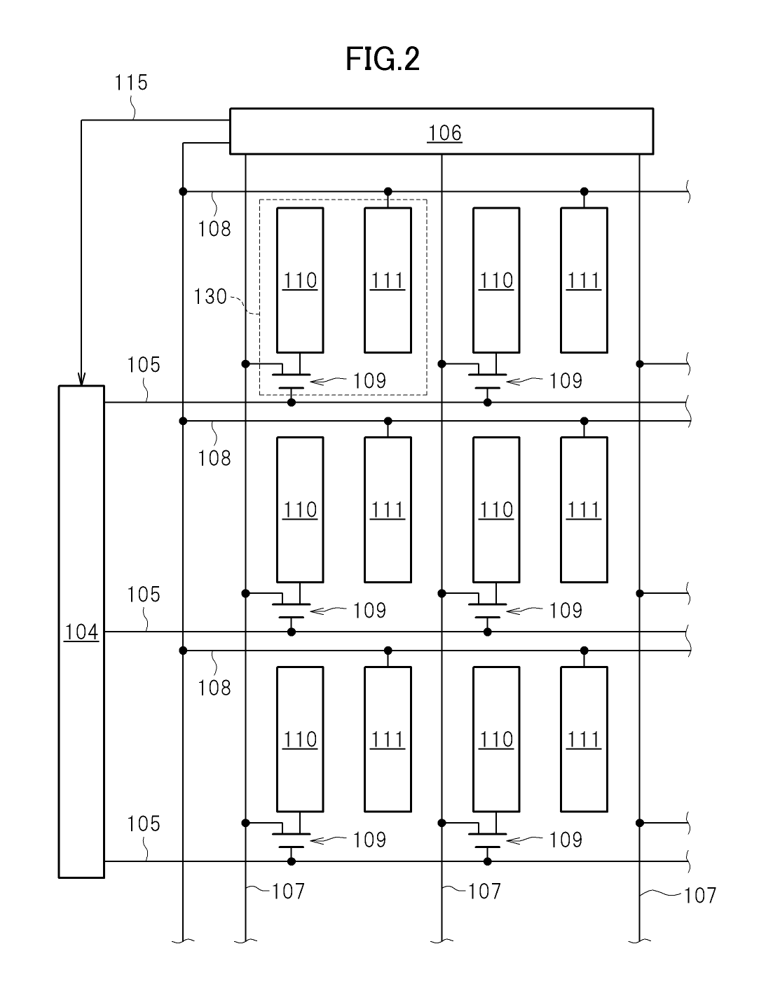

FIG. 2 is a conceptual view of a pixel circuit formed on the TFT substrate 102 illustrated in FIG. 1. As illustrated in FIG. 2, the TFT substrate 102 includes a plurality of gate signal lines 105 and a plurality of video signal lines 107. The gate signal lines 105 are horizontally arranged at approximately equal intervals. The video signal lines 107 are vertically arranged at approximately equal intervals. The gate signal lines 105 are connected to a shift register circuit 104, whereas the video signal lines 107 are connected to a driver 106.

The shift register circuit 104 includes a plurality of basic circuits (not shown) respectively corresponding to the plurality of gate signal lines 105. Each of the basic circuits includes a plurality of TFTs and capacitors. Each of the basic circuits outputs a gate signal to a corresponding one of the gate signal lines 105 in response to a control signal 115 from the driver 106. A voltage of the gate signal becomes high during a corresponding gate scanning period (HIGH-signal period) of one frame period and becomes low during the remaining period (LOW-signal period).

Pixel regions 130 are formed in a matrix pattern by partition with the gate signal lines 105 and the video signal lines 107. Each of the pixel regions 130 includes a TFT 109, a pixel electrode 110, and a common electrode 111. A gate of the TFT 109 is connected to a corresponding one of the gate signal lines 105. One of a source and a drain is connected to a corresponding one of the video signal lines 107, whereas the other one is connected to the pixel electrode 110. The common electrode 111 is connected to a corresponding one of common signal lines 108. The pixel electrode 110 and the common electrode 111 are opposed to each other.

Next, an operation of the pixel circuit configured as described above is described. The driver 106 applies a reference voltage to the common electrodes 111 through the common signal lines 108. The shift register circuit 104 controlled by the driver 106 outputs a gate signal to the gate electrodes of the TFTs 109 through the gate signal lines 105. Further, the driver 106 supplies a voltage of the video signal to the TFTs 109, to which the gate signal is output, through the video signal lines 107. The voltage of the video signal is further applied to the pixel electrodes 110 through the TFTs 109. At this time, potential differences are generated between the pixel electrodes 110 and the common electrodes 111.

The driver 106 controls the potential differences generated between the pixel electrodes 110 and the common electrodes 111 to control the orientation and the like of liquid crystal molecules of the liquid crystal material inserted between the pixel electrodes 110 and the common electrodes 111. Light from the backlight unit 103 is guided to the liquid crystal material. Therefore, by controlling the orientation of the liquid crystal molecules as described above, the amount of light from the backlight unit 103 is adjusted. As a result, an image is displayed.

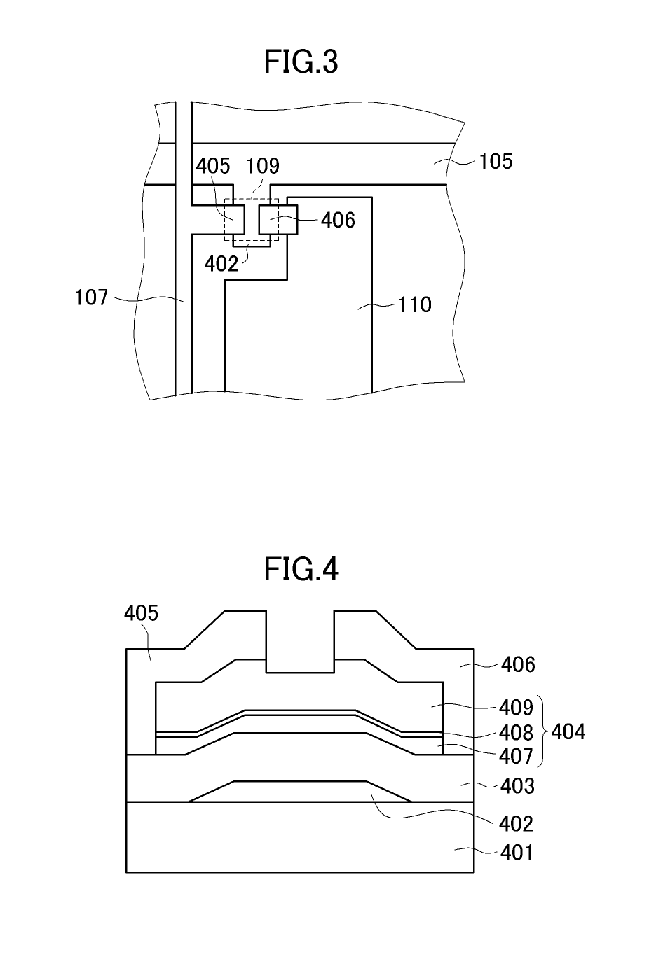

FIG. 3 is a view for illustrating a configuration of the TFT 109 illustrated in FIG. 2. Specifically, FIG. 3 illustrates apart of an upper surface of the periphery of one of the TFTs 109 of the TFT substrate 102 illustrated in FIG. 2. The configuration of the TFT illustrated in FIG. 3 is merely an example and does not limit the embodiments. For example, although FIG. 3 illustrates an example of a configuration of a so-called bottom-gate type TFT, the TFT may have a configuration of a so-called top-gate type TFT as described below.

As illustrated in FIG. 3, a gate electrode 402 is provided on the TFT substrate 102 so as to extend from the gate signal line 105 as viewed from above. Moreover, a source electrode 405 is provided so as to extend from the video signal line 107 and to partially overlap the gate electrode 402. A drain electrode 406 is provided to partially overlap the pixel electrode 110, which is provided adjacent to the gate signal line 105 and the video signal line 107, and to partially overlap the gate electrode 402. In addition, each of the TFTs 109 includes the gate electrode 402, the source electrode 405, and the drain electrode 406.

FIG. 4 is a view for illustrating a configuration of a cross section of the TFT 109 according to this embodiment. As illustrated in FIG. 4, the TFT 109 includes a glass substrate 401, the gate electrode 402, a gate insulating film 403, a multilayer channel 404, the source electrode 405, and the drain electrode 406 in the stated order from the bottom of FIG. 4.

The multilayer channel 404 includes oxide semiconductors 407 and 409 and a water-containing film 408. The oxide semiconductors 407 and 409 include, for example, as illustrated in FIG. 4, a lower-layer oxide semiconductor 407 and an upper-layer oxide semiconductor 409, respectively. The water-containing film 408 is provided between the lower-layer oxide semiconductor 407 and the upper-layer oxide semiconductor 409 so as to be held in contact with the oxide semiconductors 407 and 409. In the above, the water-containing film 408 is provided between the lower-layer oxide semiconductor 407 and the upper-layer oxide semiconductor 409. However, the water-containing film 408 may be provided so as to be held in contact with a single-layer oxide semiconductor. Specifically, the water-containing film 408 may be provided, for example, between the single-layer oxide semiconductor and the gate insulating film 403 or between the single-layer oxide semiconductor, and, the source electrode 405 and the drain electrode 406.

Preferably, the water-containing film 408 is provided at a position corresponding to 20% to 80% of a thickness of the oxide semiconductor (the sum of the thickness of the lower-layer oxide semiconductor 407 and the thickness of the upper-layer oxide semiconductor 409). Moreover, the water-containing film 408 at least before annealing described below may be a film containing water, or may be an O-atom-containing film containing O atoms or an OH-atom-containing film containing OH atoms. For example, a silicon oxide (SiO) film, a silicon nitride (SiN) film, a silicon oxynitride (SiON) film, or the like is used as a material of the water-containing film 408. Besides, an insulating film, a half-metal film, a metal film or the like may be used as the water-containing film 408.

A concentration of water or the O-atoms in the water-containing film 408 is higher than that of water or the O-atoms in the oxide semiconductors 407 and 409. Specifically, for example, the concentration of the water-containing film 408 is set to 1 atm % to 30 atom %. Further, as described later, it is desired that a thickness of the water-containing film 408 be, for example, 2 nm or smaller. Moreover, the water-containing film 408 is not necessarily required to be provided as a continuous film as illustrated in FIG. 4 and may be discontinuously provided on the lower-layer oxide semiconductor 407.

Preferably, the thickness of the oxide semiconductors (the sum of the thickness of the lower-layer oxide semiconductor 407 and the thickness of the upper-layer oxide semiconductor 409) is set to, for example, 5 nm to 200 nm. When the oxide semiconductor is formed as the single layer as described above, the thickness of the oxide semiconductor is set to, for example, 5 nm to 200 nm. For the upper-layer oxide semiconductor 409 and the lower-layer oxide semiconductor 407, the same material and different materials may be used. As a material of the oxide semiconductors 407 and 409, for example, In—Ga—Zn—O or an amorphous or crystalline oxide semiconductor containing at least one element selected from In, Ga, Zn, and Sn is used as described later.

As the gate electrode 402, for example, a single layer or multilayered structure of a low-resistance metal such as Mo, W, Al, Cu, a Cu—Al alloy, an Al—Si alloy, and an Mo—W alloy, is used. As the gate insulating film 403, for example, a single layer or a multilayered structure of an insulating film such as a silicon oxide (SiO) film, a silicon nitride (SiN) film, and a silicon oxynitride (SiON) film is used. As the source electrode 405 and the drain electrode 406 (including a wiring portion to be connected to the source electrode 405 or the drain electrode 406), for example, a single layer or a multilayered structure of a low-resistance metal such as Mo, W, Al, Cu, a Cu—Al alloy, an Al—Si alloy, and an Mo—W alloy is used.

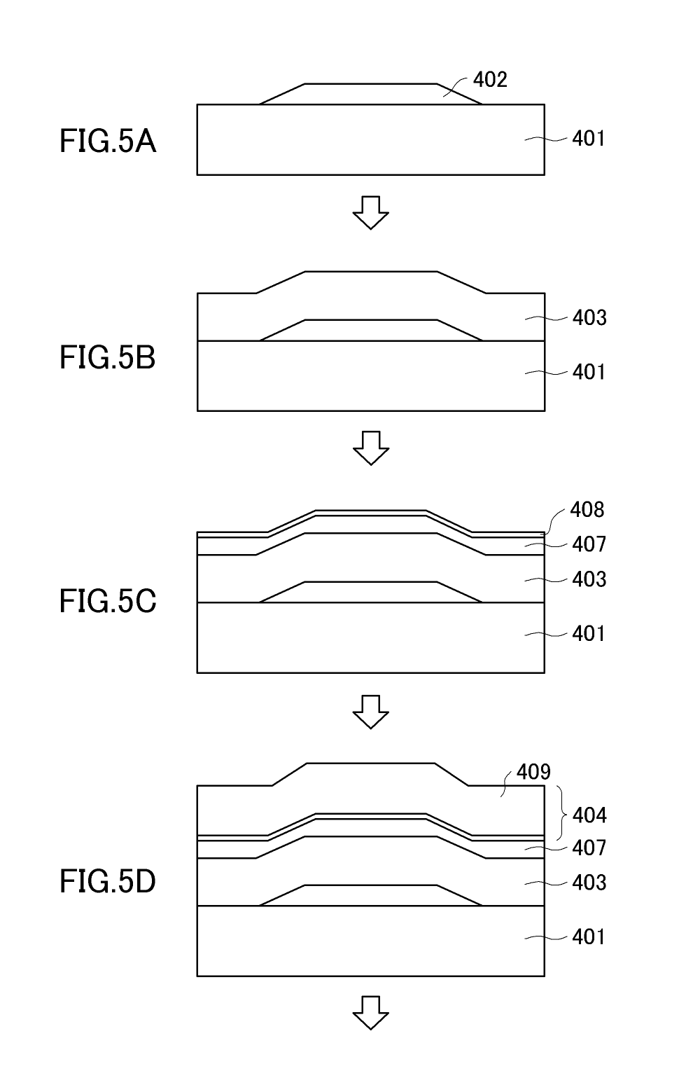

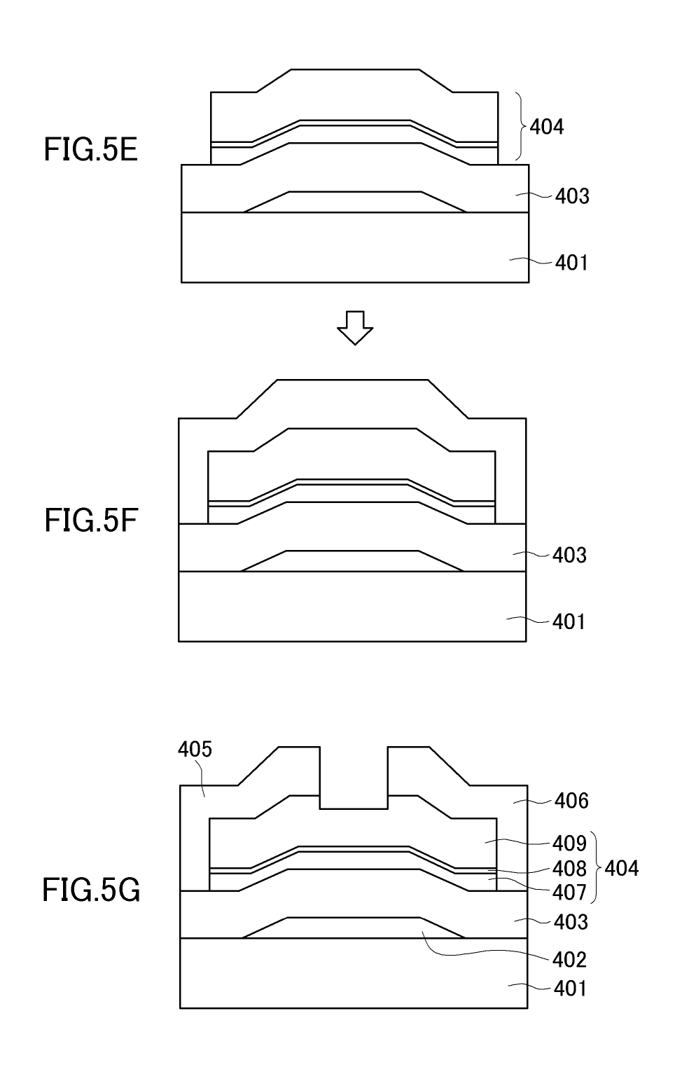

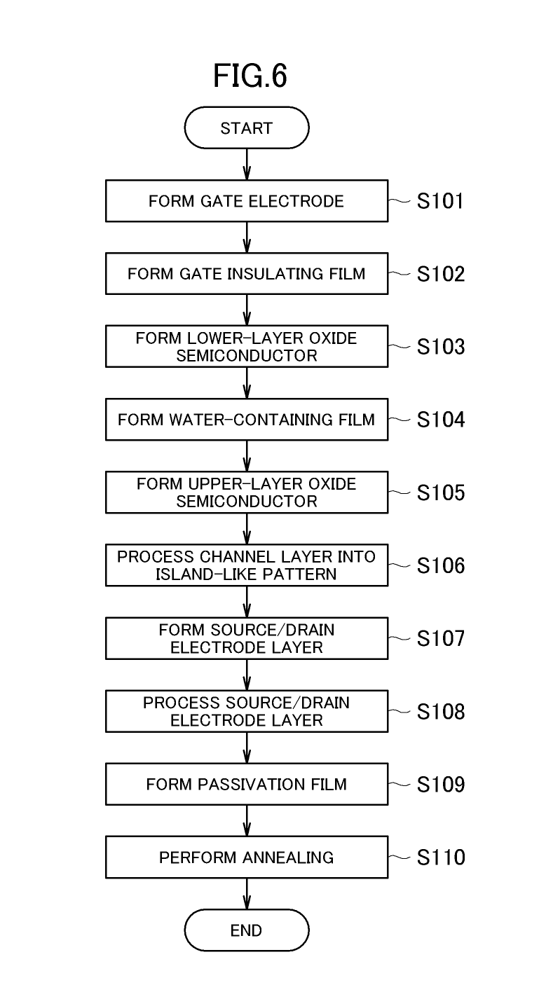

Next, referring to FIGS. 5A to 5G and 6, a manufacturing method for the TFT according to this embodiment is described. FIGS. 5A to 5G are views, each illustrating a sectional structure of the TFT in each step of a flow of the manufacturing method. FIG. 6 is a flowchart for illustrating the flow of the manufacturing method according to this embodiment.

As illustrated in FIG. 5A, first, a gate electrode layer forming the gate electrode 402, which includes, for example, a layer made of Al at a thickness of about 300 nm and a layer made of Mo at a thickness of about 50 nm, is formed by using a sputtering device. The gate electrode layer is processed into an island-like shape by known photolithography and wet etching or dry etching to form the gate electrode 402 (Step S101). Alternatively, the gate electrode layer may be also formed as a single layer made of a low-resistance metal such as Mo, W, Al, Cu, a Cu—Al alloy, an Al—Si alloy, or an Mo—W alloy and a multilayered structure thereof.

Next, as illustrated in FIG. 5B, for example, a silicon oxide (SiO) film, which serves as the gate insulating film 403, is formed to have a thickness of about 200 nm at a film-formation temperature of 350° C. by using SiH₄ and N₂O as film-formation gases in a plasma-enhanced chemical vapor deposition (PECVD) device (Step S102). The gate insulating film 403 may be a single layer of an insulating film such as a silicon oxide (SiO) film, a silicon nitride (SiN) film, or a silicon oxynitride (SiON) film, or a multilayered structure thereof.

Next, as illustrated in FIGS. 5C and 5D, the multilayer channel 404 including the lower-layer oxide semiconductor 407, the water-containing layer 408, and the upper-layer oxide semiconductor 409 is formed. For example, an oxide of In—Ga—Zn—O is used for the lower-layer oxide semiconductor 407 and the upper-layer oxide semiconductor 409.

Specifically, first, for example, as illustrated in FIG. 5C, a film made of the In—Ga—Zn—O oxide is formed to have a thickness of 25 nm using In₂Ga₂ZnO₂ as a target material and adding oxygen to an Ar gas by the sputtering device to form the lower-layer oxide semiconductor 407 (Step S103). Then, the water-containing film 408 is formed to have a thickness of about 1 nm at a temperature of 400° C. using TEOS and O₂ as film-formation gases in the PECVD device (Step S104). Next, as illustrated in FIG. 5D, a film made of an oxide of In—Ga—Zn—O (IGZO) is formed to have a thickness of 25 nm using In₂Ga₂ZnO₂ as a target material with the addition of oxygen to an Ar gas by a DC sputtering device to form the upper-layer oxide semiconductor 409 (Step S105).

Instead of In—Ga—Zn—O described above, an amorphous or crystalline oxide semiconductor containing at least one element selected from In, Ga, Zn, and Sn may be used as a material of the oxide semiconductors 407 and 409. Specifically, for example, an In—Ga—Zn oxide, an In—Ga oxide, an In—Zn oxide, an In—Sn oxide, a Zn—Ga oxide, a Zn oxide, or the like may be used. Moreover, for the lower-layer oxide semiconductor 407 and the upper-layer oxide semiconductor 409, the same material or different materials may be used. In the case where different materials are used, IGZO is used for the lower-layer oxide semiconductor 407, whereas ITO is used for the upper-layer oxide semiconductor 409, for example.

The TEOS film corresponding to the water-containing film 408 is originally an insulating film. However, when a thickness of the TEOS film is about 2 nm or smaller, a current flows through the water-containing film 408 as a tunnel current and therefore, does not affect an ON-current. On the other hand, when the thickness of the TEOS film is larger than about 2 nm, the TEOS film functions as an insulating film and therefore, the ON-current is reduced drastically. Therefore, the TEOS film corresponding to the water-containing film 408 is formed to have a thickness of about 2 nm or smaller.

It may be difficult to form the TEOS film having a thickness of about 2 nm or smaller uniformly. Therefore, in some cases, the TEOS film is formed in an island-like pattern and is not formed in the other region. In this case, SiO, Si, O₂, OH and the like corresponding to residues of the film-formation gas remain in the region where the film is not formed. The residues O₂ and OH diffuse into the IGZO film by annealing, which is described later, to oxygen-terminate the IGZO film so as to contribute to the improvement of the ON-current. Therefore, the water-containing film 408 may be formed into the island-like pattern.

Next, as illustrated in FIG. 5E, the multilayer channel 404 is processed into the island-like pattern by known photolithography and wet etching or dry etching (Step S106).

Next, as illustrated in FIG. 5F, the source electrode 405 and the drain electrode 406 (including a wiring) are formed. Specifically, a multilayered structure (source/drain electrode layer) including a layer of Ti at 50 nm, a layer of Al at 400 nm, and a layer of Ti at 50 nm is formed by the sputtering device (Step S107). The source/drain electrode layer may be a single layer made of a low-resistance metal such as Mo, W, Al, Cu, a Cu—Al alloy, an Al—Si alloy, or an Mo—W alloy, and a multilayered structure thereof.

Next, as illustrated in FIG. 5G, the source/drain electrode layer is processed into a predetermined shape to form the source electrode 405, the drain electrode 406, and the wiring portion thereof (Step S108). Shapes illustrated in FIG. 5G are merely an example and therefore, the shapes of the source electrode 405 and the drain electrode 406 are not limited thereto.

Next, for example, a silicon oxide film, which serves as a passivation film (not shown), is formed to have a thickness of about 400 nm at a film-formation temperature of about 250° C. by using SiH₄ and N₂O as film-formation gases by the PECVD device (Step S109).

The passivation film may also be an insulating film such as a silicon nitride (SiN) film, a silicon oxynitride (SiON) film, or other metal oxide films. As the film-formation method, sputtering or vapor deposition may also be used.

As the final step, annealing is performed at about 300° C. in a nitrogen atmosphere for about 1 hour (Step S110). In this manner, water contained in the water-containing film 408 is diffused into the IGZO film so that the In—Ga—Zn—O oxide is oxygen-terminated. As a result, the ON-current of the TFT 109 is improved. Although the annealing is performed as the final step in the above, the annealing may be performed in the different step as long as the annealing is performed after the formation of the upper-layer oxide semiconductor 409 (Step S105).

According to this embodiment, the water-containing film 408 acts as an oxygen- or water-storage layer. Therefore, by the annealing performed during the formation of the water-containing film 408 or after the formation of the TFT 109, oxygen and water is more uniformly and sufficiently thermally diffused in the oxide semiconductors 407 and 409. As a result, the mobility of the oxide semiconductors 407 and 409 is increased to increase the ON-current of the TFT 109. Further, a rise of a drain current with respect to a gate voltage becomes steep to improve switching characteristics (reduce an S-value). Moreover, time required for the annealing is further reduced. As a result, a size of a frame region in the display apparatus 100 is reduced, and the definition of the display apparatus 100 is enhanced.

The present invention is not limited to the embodiment described above, and various variations are possible. For example, the configuration described above in the embodiment may be replaced by substantially the same configuration, a configuration having the same functions and effects, or a configuration which enables the achievement of the same object.

### Second Embodiment

Next, a second embodiment of the present invention is described. The second embodiment mainly differs from the first embodiment in that the so-called bottom-gate type thin film transistor structure is used in the first embodiment described above, but a so-called top-gate type thin film transistor structure is used in the second embodiment. In the following, the description of the similar points as those of the first embodiment is omitted.

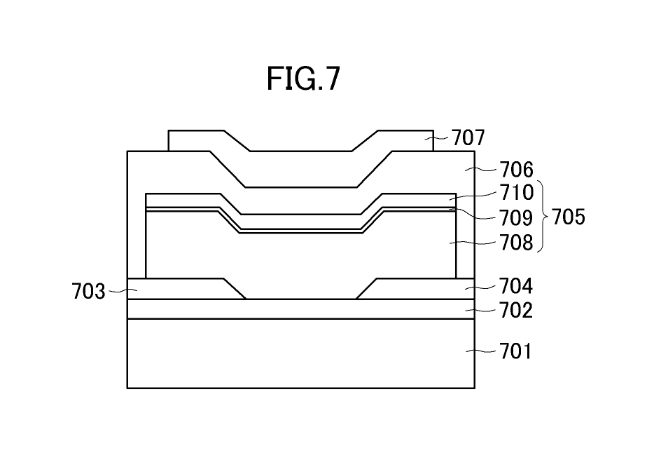

FIG. 7 is a view for illustrating a configuration of a cross section of the TFT 109 according to this embodiment. As illustrated in FIG. 7, the TFT 109 includes a glass substrate 701, a contamination-barrier film 702, a source electrode 703 and a drain electrode 704, a multilayer channel 705, a gate insulating film 706, and a gate electrode 707 in the stated order from the bottom of FIG. 7. As the contamination-barrier film 702, for example, a single layer of an insulating film such as a silicon oxide (SiO) film, a silicon nitride (SiN) film, or a silicon oxynitride (SiON) film, or a multilayered structure thereof is used. The multilayer channel 705 is configured by laminating a lower-layer oxide semiconductor 708, a water-containing film 709, and an upper-layer oxide semiconductor 710 as in the case of the first embodiment described above.

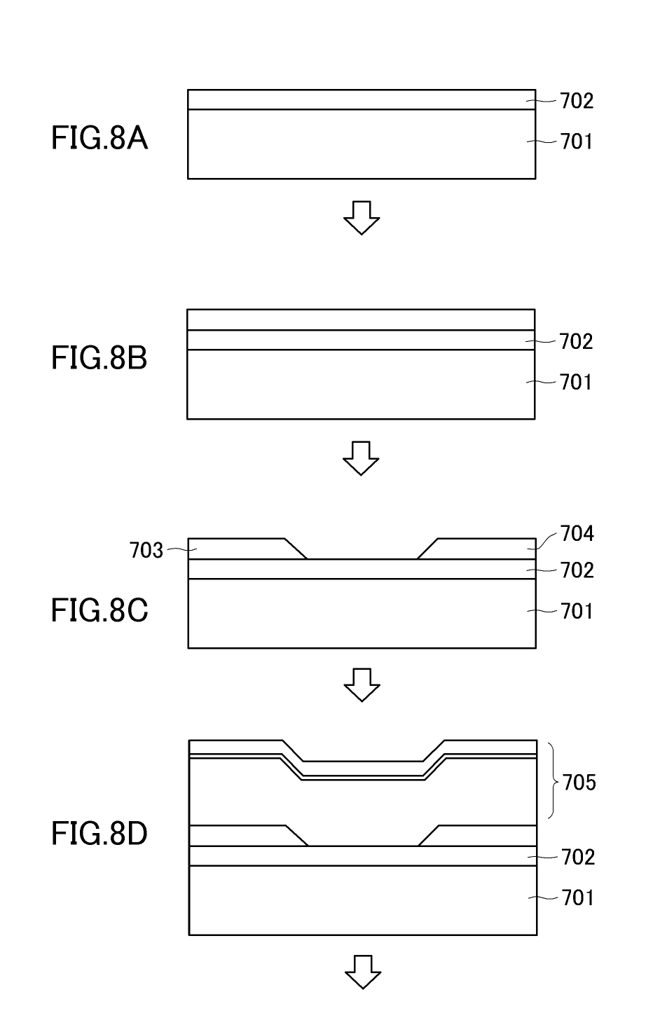

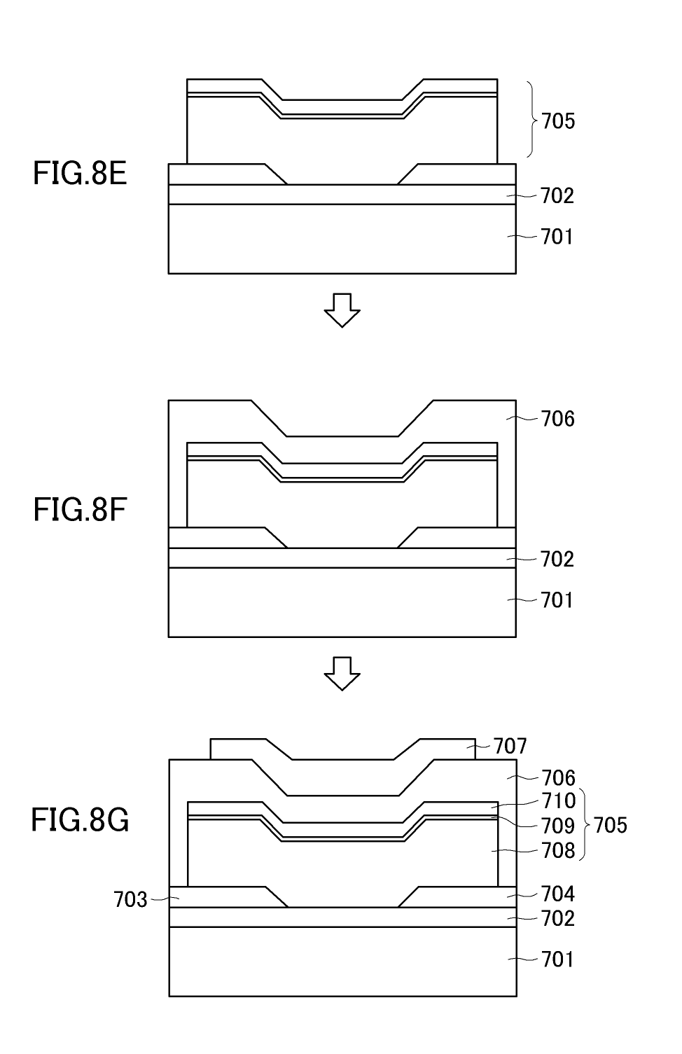

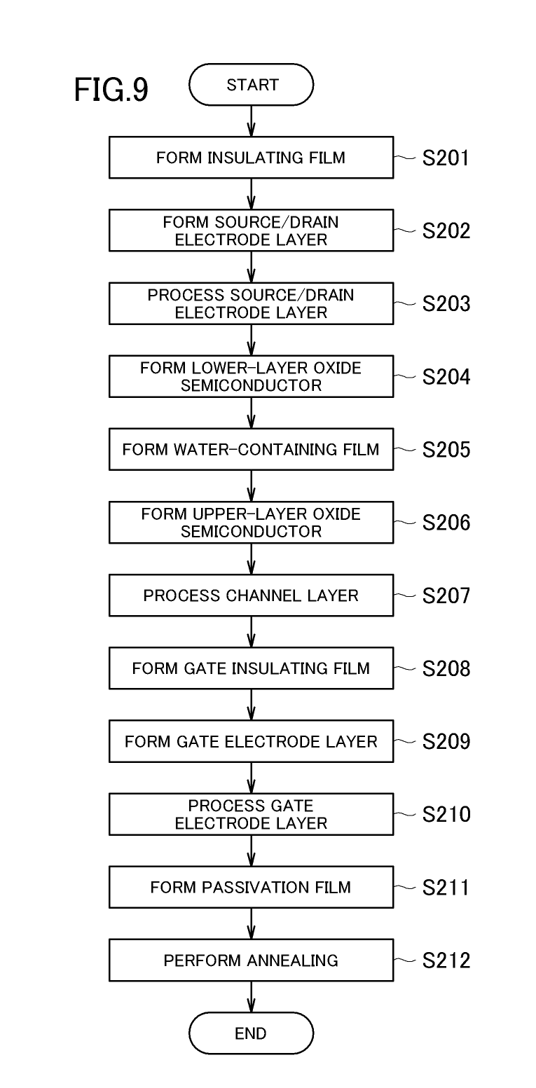

Next, referring to FIGS. 8A to 8G and 9, a manufacturing method for the TFT 109 according to this embodiment is described. FIGS. 8A to 8G are views, each illustrating a sectional structure in each step of a flow of the manufacturing method. FIG. 9 is a flowchart for illustrating the flow of the manufacturing method according to this embodiment.

First, as illustrated in FIG. 8A, a silicon nitride film corresponding to the contamination-barrier film 702 (insulating film) is formed on the glass substrate 701 by using, for example, the PECVD device (Step S201).

As illustrated in FIG. 8B, the source electrode 703, the drain electrode 704, and a wiring portion thereof are formed. For example, a multilayered structure (source/drain electrode layer) including a layer of Ti at 50 nm, a layer of Al at 400 nm, and a layer of Ti at 50 nm is formed by using the sputtering device (Step S202). Alternatively, the source/drain electrode layer may be a single layer made of a low-resistance metal such as Mo, W, Al, Cu, a Cu—Al alloy, an Al—Si alloy, or an Mo—W alloy, and a multilayered structure thereof.

As illustrated in FIG. 8C, the source/drain electrode layer is processed to form the source electrode 703, the drain electrode 704, and the like (Step S203). Shapes illustrated in FIG. 8C are merely an example, and the shapes of the source electrode 703 and the drain electrode 704 are not limited thereto.

Next, as illustrated in FIG. 8D, a multilayer channel layer forming the multilayer channel 705 including the lower-layer oxide semiconductor 708, the water-containing layer 709, and the upper-layer oxide semiconductor 710 is formed. For example, an oxide of In—Ga—Zn—O may be used for the lower-layer oxide semiconductor 708 and the upper-layer oxide semiconductor 710.

Specifically, for example, first, a film made of the In—Ga—Zn—O oxide is formed to have a thickness of about 25 nm using In₂Ga₂ZnO₇ as a target material and adding oxygen to an Ar gas by using the sputtering device to form a lower-layer oxide semiconductor layer for forming the lower-layer oxide semiconductor 708 (Step S204).

Next, the water-containing film 709 is formed to have a thickness of about 1 nm at a temperature of 400° C. using TEOS and O₂ as film-formation gases in the PECVD device (Step S205).

Next, a film made of an oxide of In—Ga—Zn—O (IGZO) is formed to have a thickness of about 25 nm using In₂Ga₂ZnO₇ as a target material and adding oxygen to an Ar gas by a DC sputtering device. In this manner, an upper-layer oxide semiconductor layer forming the upper-layer oxide semiconductor 710 is formed (Step S206).

As in the case of the first embodiment described above, instead of In—Ga—Zn—O described above, an amorphous or crystalline oxide semiconductor containing at least one element selected from In, Ga, Zn, and Sn may be used as a material of the oxide semiconductors 708 and 710. Specifically, for example, an In—Ga—Zn oxide, an In—Ga oxide, an In—Zn oxide, an In—Sn oxide, a Zn—Ga oxide, a Zn oxide, or the like may be used. Moreover, for the lower-layer oxide semiconductor 708 and the upper-layer oxide semiconductor 710, the same material and different materials may be used. In the case where different materials are used, IGZO is used for the lower-layer oxide semiconductor 708, whereas ITO is used for the upper-layer oxide semiconductor 710, for example.

As in the case of the first embodiment described above, the TEOS film corresponding to the water-containing film 709 is originally an insulating film. However, when a thickness of the TEOS film is about 2 nm or smaller, a current flows through the water-containing film 709 as a tunnel current and therefore, does not affect an ON-current. On the other hand, when the thickness of the TEOS film is larger than about 2 nm, the TEOS film functions as an insulating film and therefore, the ON-current is reduced drastically. Therefore, the TEOS film corresponding to the water-containing film 709 is formed to have a thickness of 2 nm or smaller.

As in the case of the first embodiment described above, further, it may be difficult to form the TEOS film having a thickness of about 2 nm or smaller uniformly. Therefore, in some cases, the TEOS film is formed in an island-like pattern and is not formed in the other region. In this case, SiO, Si, O₂, OH, and the like corresponding to residues of the film-formation gas remain in the region where the film is not formed. The residues O₂ and OH diffuse into the IGZO film by annealing, which is described later, to oxygen-terminate the IGZO film so as to contribute to the improvement of the ON-current. Therefore, the water-containing film 709 may be formed into the island-like pattern. As a material of the water-containing film 709, a silicon oxide (SiO) film, a silicon nitride (SiN) film, a silicon oxynitride (SiON) film, or an insulating film made of AlO or TiO may also be used.

Next, as illustrated in FIG. 8E, the multilayer channel layer is processed into the island-like pattern by known photolithography and wet etching or dry etching to form the multilayer channel 705 (Step S207).

Next, as illustrated in FIG. 8F, for example, a silicon oxide film, which serves as the gate insulating film 706, is formed to have a thickness of about 200 nm at a film-formation temperature of 350° C. by using SiH₄ and N₂O as film-formation gases in the PECVD device (Step S208). The gate insulating film 706 may be a single layer of an insulating film such as a silicon oxide (SiO) film, a silicon nitride (SiN) film, or a silicon oxynitride (SiON) film, and a multilayered structure thereof. A laminate (gate electrode layer) of a layer made of Mo at 50 nm, a layer made of Al at 300 nm, and a layer made of Mo at 50 nm for forming the gate electrode 707 is formed by the sputtering device (Step S209). As a material for forming the gate electrode 707, a single layer of a low-resistance metal such as Mo, W, Al, Cu, a Cu—Al alloy, an Al—Si alloy, and an Mo—W alloy, and a multilayered structure thereof may also be used.

Next, as illustrated in FIG. 8G, the gate electrode layer is processed into the island-like pattern by photolithography and wet etching or dry etching to form the gate electrode 707 (Step S210).

Next, for example, a silicon oxide film, which serves as a passivation film (not shown), is formed to have a thickness of about 400 nm at a film-formation temperature of 250° C. by using SiH₄ and N₂O as film-formation gases by the PECVD device (Step S211). The passivation film may also be an insulating film such as a silicon nitride (SiN) film, a silicon oxynitride (SiON) film, or other metal oxide films. As the film-formation method, sputtering or vapor deposition may also be used.

As the final step, annealing is performed at 300° C. in a nitrogen atmosphere for about 1 hour (Step S212). In this manner, as in the case of the first embodiment described above, water contained in the water-containing film 709 is diffused into the IGZO film so that the In—Ga—Zn—O oxide is oxygen-terminated. As a result, the ON-current of the TFT 109 is improved. Although the annealing is performed as the final step in the above, the annealing may be performed in the different step as long as the annealing is performed after the formation of the upper-layer oxide semiconductor 710 (Step S206).

As in the case of the first embodiment described above, according to this embodiment, the water-containing film 709 acts as an oxygen- or water-storage layer. Therefore, by the annealing performed during the formation of the water-containing film 709 or after the formation of the TFT 109, oxygen and water is more uniformly and sufficiently thermally diffused in the oxide semiconductors 708 and 710. As a result, the mobility of the oxide semiconductors 708 and 710 is further increased to increase the ON-current of the TFT 109. Further, a rise of a drain current with respect to a gate voltage becomes steep to improve switching characteristics (reduce an S-value). Moreover, time required for the annealing is further reduced.

The present invention is not limited to the first and second embodiments described above, and various variations are possible. For example, the configuration described above in the first and second embodiments may be replaced by substantially the same configuration, a configuration having the same functions and effects, or a configuration which enables the achievement of the same object.

For example, although the liquid crystal display apparatus has been mainly described above, the display apparatus to which the present invention is applied is not limited thereto. For example, the present invention may be applied to a display apparatus using various types of light-emitting elements such as organic EL elements, inorganic EL elements, and field-emission devices (FEDs). Further, although the TFT 109 provided in the pixel region 130 has been described above, the TFT is not limited thereto. The present invention may be applied to TFTs that are included in the shift register circuit 104 or the driver 106.

The image display apparatus according to the embodiments described above may be used as various types of display apparatus for information display such as a display for personal computer, a display for TV broadcast reception, or a display for advertisement display. Moreover, the image display apparatus may also be used as a display section of various electronic devices such as a digital still camera, a video camera, a car navigation system, a car audio system, a game machine, and a personal digital assistance. A first electrode layer recited in the claims includes, for example, the electrode layer which forms the gate electrode 402 or the electrode layer which forms the source electrode 703 and the drain electrode 704. A second electrode layer recited in the claims includes the electrode layer which forms the source electrode 405 and the drain electrode 406 or the electrode layer which forms the gate electrode 707.

What is claimed is:

1. A semiconductor device comprising:
a gate electrode;
a gate insulating film provided so as to cover one surface of the gate electrode;
an oxide semiconductor provided so as to overlap the gate insulating film;
a source electrode and a drain electrode, which are provided so as to overlap the oxide semiconductor; and
an oxygen-atom-containing film provided between the gate insulating film, and, the source electrode and the drain electrode, so as to be held in contact with the oxide semiconductor.

2. The semiconductor device according to claim 1, wherein:
the oxide semiconductor includes a first oxide semiconductor layer and a second oxide semiconductor layer; and
the oxygen-atom-containing film is provided between the first oxide semiconductor layer and the second oxide semiconductor layer.

3. The semiconductor device according to claim 1, wherein the oxygen-atom-containing film comprises a water-containing film containing water.

4. The semiconductor device according to claim 3, wherein a water concentration of the water-containing film is higher than a water concentration of the oxide semiconductor.

5. The semiconductor device according to claim 3, wherein a water concentration of the water-containing film is 1 atm % to 30 atm %.

6. The semiconductor device according to claim 1, wherein the oxygen-atom-containing film is provided at a position corresponding to 20% to 80% of a thickness of the oxide semiconductor.

7. The semiconductor device according to claim 1, wherein the oxygen-atom-containing film is formed as a discontinuous film.

8. The semiconductor device according to claim 1, wherein a thickness of the oxide semiconductor is 5 nm to 200 nm.

9. The semiconductor device according to claim 2, wherein a material of the first oxide semiconductor layer is different from a material of the second oxide semiconductor layer.

10. A manufacturing method for a semiconductor device comprising:
forming at least a first electrode layer on a substrate;
forming a channel layer including an oxide semiconductor layer and an oxygen-atom-containing film on the substrate on which the at least the first electrode layer is formed;
forming at least a second electrode layer on the substrate on which the channel layer is formed; and
diffusing oxygen atoms contained in the oxygen-atom-containing film into the oxide semiconductor layer.

11. The manufacturing method for the semiconductor device according to claim 10, wherein the oxide semiconductor layer includes a first oxide semiconductor layer and a second oxide semiconductor layer, and
wherein the forming a channel layer comprises:
forming at least the first oxide semiconductor layer on the substrate on which the first electrode layer is formed;
forming the oxygen-atom-containing film on the first oxide semiconductor layer; and
forming the second oxide semiconductor layer on the oxygen-atom-containing film.
